(19) United States
(12) Patent Application Publication
(10) Pub. No.: US 2026/0117418 A1
(43) Pub. Date: Apr. 30, 2026

(54) SiC SINGLE CRYSTAL, SiC SUBSTRATE, EPITAXIAL WAFER, METHOD FOR MANUFACTURING SiC SUBSTRATE

(71) Applicant: Resonac Corporation, Tokyo (JP)

(72) Inventor: Yohei FUJIKAWA, Tokyo (JP)

(73) Assignee: Resonac Corporation, Tokyo (JP)

(21) Appl. No.: 19/371,407

(22) Filed: Oct. 28, 2025

(30) Foreign Application Priority Data
Oct. 29, 2024 (JP) 2024-189937

(51) Int. Cl. C30B 29/36; C30B 23/02; C30B 33/00

(52) U.S. Cl. CPC C30B 29/36; C30B 23/025; C30B 33/00

(57) ABSTRACT

The invention provides an SiC single crystal, an SiC substrate, an epitaxial wafer, and a method for manufacturing an SiC substrate, in which 4H is a main constituent and conversion to a 6H polytype does not occur. The SiC single crystal includes 3C in a facet region and 4H is included in a non-facet region.

### BACKGROUND OF THE INVENTION

### Field of the Invention

The present invention relates to an SiC single crystal, an SiC substrate, an epitaxial wafer, and a method for manufacturing an SiC substrate.

### Description of Related Art

Silicon carbide (SiC) has a dielectric breakdown field one order of magnitude higher and a bandgap three times that of silicon (Si). In addition, SiC has a thermal conductivity approximately three times higher than Si. For this reason, SiC is expected to be applied to power devices, high-frequency devices, high-temperature operating devices, and the like.

SiC exists in a plurality of polytypes (polymorphs) having different crystal structures. Among these polytypes, examples of those of which the probability of occurrence is particularly high and for which application is being considered include cubic 3C-SiC, hexagonal 4H-SiC and 6H-SiC, and rhombohedral 15R-SiC. Among these, in many of the devices developed using SiC, substrates using 4H-SiC having high electron mobility are often used (for example, refer to Patent Documents 1 and 2).

In addition, partial regions different from each other are formed on a growth interface of a growing SiC single crystal. For example, in a region close to an outer peripheral surface of an SiC single crystal, a facet region having a nearly flat and smooth surface structure (surface morphology) with a very high ratio of step depth or step width to the step height of crystal growth steps is formed.

In this manner, in an SiC single crystal, regions having growth modes different from each other, such as a region referred to as a facet region and a region referred to as a non-facet region are formed during its growth process. It is known that a facet region and a non-facet region have different physical properties, such as resistivity and defect density, due to the difference between their growth modes.

### PATENT DOCUMENT

Patent Document 1 Japanese Unexamined Patent Application, First Publication No. 2019-127415

Patent Document 2 Japanese Unexamined Patent Application, First Publication No. 2022-160660

### SUMMARY OF THE INVENTION

However, in the related art, when growing a 4H-SiC single crystal ingot, conversion to a 6H-SiC polytype, which is also constituted of the same hexagonal crystal, is likely to occur. Such polytype conversion from 4H to 6H occurs when a c-plane facet changes from 4H to 6H and spreads over the entire growth surface by step-flow growth from the c-plane facet. At this time, micropipes are generated due to a mismatch occurring at the 4H/6H interface.

It is considered that such micropipes are formed by aggregation of a plurality of threading screw dislocations and a plurality of threading edge dislocations. Further, a substrate cut out from this will have micropipes existing over its entire surface, failing to satisfy the quality of an SiC substrate for semiconductor devices. Thus, a 4H-SiC single crystal which is not converted to a 6H polytype has been desired.

The present invention has been made in consideration of such a technical background, and an object thereof is to provide an SiC single crystal, an SiC substrate, an epitaxial wafer, and a method for manufacturing an SiC substrate, in which 4H is a main constituent and conversion to a 6H polytype does not occur.

The present inventors have newly discovered that conversion of 4H to 6H in a subsequent crystal growth region can be curbed by mixing a 3C polytype into a c-plane facet. In addition, they have newly discovered that such mixing of a 3C polytype into a c-plane facet can be realized by momentarily setting the crystal growth rate to exceed 5 mm/h.

In order to resolve the foregoing problems, an SiC single crystal, an SiC substrate, an epitaxial wafer, and a method for manufacturing an SiC substrate of an embodiment of the present invention provide the following means.

(1) In a Sic single crystal according to Aspect 1 of the present invention, 3C is included in a facet region and 4H is included in a non-facet region.

(2) According to Aspect 2 of the present invention, in the SiC single crystal according to Aspect 1, the SiC single crystal is an ingot after crystal growth.

(3) According to Aspect 3 of the present invention, in the Sic single crystal according to Aspcect 1, the Sic single crystal is an ingot processed into a cylindrical shape.

(4) According to Aspect 4 of the present invention, in the SiC single crystal according to Aspect 2, the facet region exists within a region having a width of 20 mm from an outer peripheral surface toward a center.

(5) According to Aspect 5 of the present invention, in the SiC single crystal according to any one of Aspects 1 to 4, the facet region has a threading screw dislocation.

(6) A method for manufacturing the SiC substrate according to Aspect 6 of the present invention is a method for manufacturing an SiC substrate using the SiC single crystal according to Aspect 1 or 2. The method includes forming an SiC substrate having an arbitrary diameter by removing an outer peripheral region with an arbitrary width from an outer peripheral surface toward a center.

(7) In an SiC single crystal according to Aspect 7 of the present invention, the number of threading screw dislocations existing in a facet region and a region on an outward side thereof is larger than the number of threading screw dislocations existing on a center side relative to the facet region.

(8) In an SiC epitaxial wafer according to Aspect 8 of the present invention, an epitaxial layer is formed on one main surface of an SiC substrate where the number of threading screw dislocations existing in a facet region and a region on an outward side thereof is larger than the number of threading screw dislocations existing on a center side relative to the facet region.

(9) In an SiC single crystal according to Aspect 9 of the present invention, the number of threading screw dislocations existing in a facet region is larger than the number of threading screw dislocations existing on an outward side relative to the facet region.

(10) In an SiC epitaxial wafer according to Aspect 10 of the present invention, an epitaxial layer is formed on one main surface of an SiC substrate where the number of threading screw dislocations existing in a facet region is larger than the number of threading screw dislocations existing on an outward side relative to the facet region.

(11) According to Aspect 11 of the present invention, in the SiC single crystal of Aspect 7 or 9, the SiC single crystal is an ingot processed into a cylindrical shape.

(12) According to Aspect 12 of the present invention, in the SiC single crystal of Aspect 7 or 9, the SiC single crystal is a substrate.

(13) In a Sic substrate according to Aspect 13 of the present invention, 3C or a polycrystal with a regular orientation is provided in an edge exclusion region on an outer peripheral side, and 4H is included on a center side relative to the edge exclusion region.

(14) In a Sic epitaxial wafer according to Aspect 14 of the present invention, an epitaxial layer is formed on one main surface of an SiC substrate where 3C or a polycrystal with a regular orientation is provided in an edge exclusion region on an outer peripheral side, and 4H is included on a center side relative to the edge exclusion region.

According to an embodiment of the present invention, it is possible to provide an SiC single crystal, an SiC substrate, an epitaxial wafer, and a method for manufacturing an SiC substrate, in which 4H is a main constituent and conversion to a 6H polytype does not occur.

### BRIEF DESCRIPTION OF THE DRAWINGS

FIG. 1 is an enlarged explanatory view of an end portion of an SiC single crystal ingot in an x direction.

FIG. 2A is an explanatory view showing a difference in crystal growth between a c-plane facet F and other parts.

FIG. 2B is an explanatory view showing a difference in crystal growth between a c-plane facet F and other parts.

FIG. 3 is a schematic cross-sectional view including a facet region of an SiC single crystal of the present embodiment.

FIG. 4 is a schematic cross-sectional view showing occurrence of threading screw dislocations in the facet region.

FIG. 5 is a schematic cross-sectional view showing an in-plane position of the facet region in the SiC single crystal.

FIG. 6 is a schematic cross-sectional view showing an in-plane position of the facet region in the SiC single crystal according to another embodiment.

FIG. 7 is a schematic graph showing an example of controlling a growth rate to form 3C-SiC.

### DETAILED DESCRIPTION OF THE INVENTION

Hereinafter, an embodiment of the present invention will be described in detail with reference to the drawings. In the drawings used in the following description, in order to make characteristics easy to understand, characteristic parts may be shown in an enlarged manner for the sake of convenience, and dimensional ratios or the like of each constituent element may not be the same as the actual values thereof. In addition, materials, dimensions, and the like shown in the following description are merely examples. The present invention is not necessarily limited thereto and can be suitably changed and performed within a range in which the effects thereof are not changed.

An SiC single crystal according to the embodiment of the present invention will be described.

In the SiC single crystal of the embodiment of the present invention, cubic 3C-SiC is included in a facet region which is a region including a c-plane facet, and hexagonal 4H-SiC is included in a non-facet region which is a region other than this facet region.

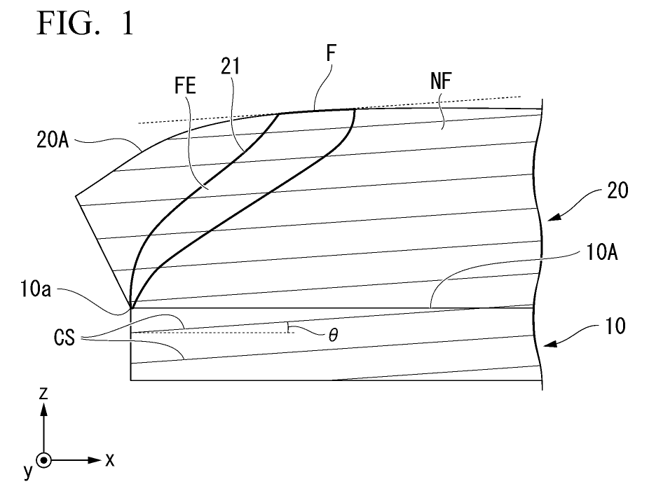

First, the c-plane facet and the facet region will be described. FIG. 1 is an enlarged explanatory view of an end portion of an SiC single crystal ingot in an x direction. An SiC single crystal 20 is grown on a seed crystal 10. Crystal planes CS of the seed crystal 10 and a single crystal 20 are inclined in the x direction with respect to a first surface 10A by an offset angle θ. A crystal growth surface 20A of the SiC single crystal 20 is formed to have a shape projecting in a z direction. When the crystal growth surface 20A has a shape projecting in the z direction, a part of the crystal growth surface 20A becomes parallel to the crystal planes CS.

On this crystal growth surface 20A, a surface parallel to the crystal planes CS is a c-plane facet F. This c-plane facet F is parallel to the crystal planes CS, and it can be said that a c-plane ((0001) plane) is exposed. Within the single crystal 20, the position where the c-plane facet is formed can be confirmed as a trajectory 21, and an inward region demarcated by this trajectory 21 will be regarded as a facet region FE. In addition, the outward side of this facet region FE will be regarded as a non-facet region NF.

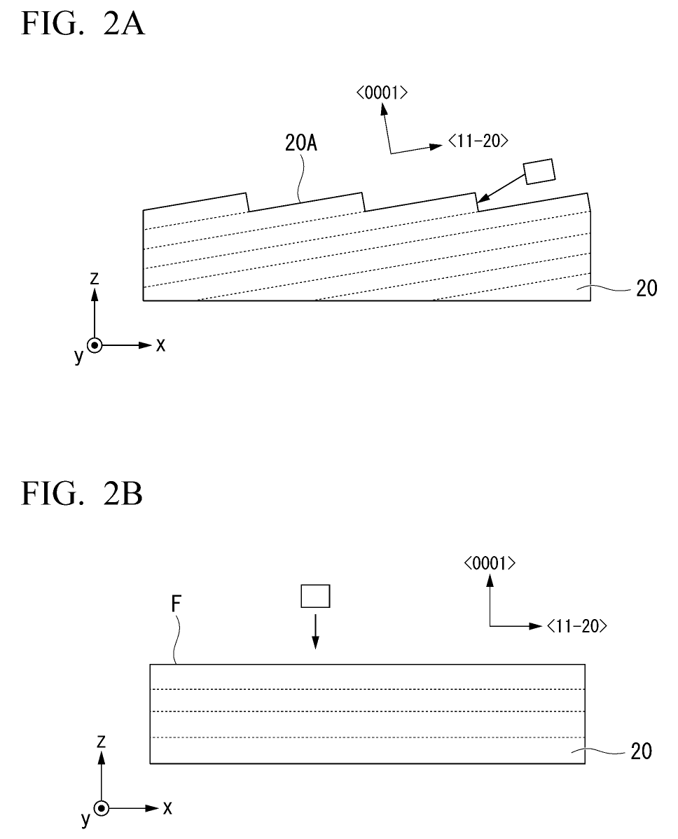

The c-plane facet F differs from the parts of the crystal growth surface 20A other than the c-plane facet F in crystal growth behavior. FIG. 2 is an explanatory view showing a difference in crystal growth between the c-plane facet F and other parts. FIG. 2A shows crystal growth in a part undergoing step-flow growth, and FIG. 2B shows crystal growth on the c-plane facet F.

As shown in FIG. 2A, on the crystal growth surface 20A other than the c-plane facet F, step-flow growth occurs. In step-flow growth, a crystal grows in an a-plane direction (<11-20> direction). The SiC single crystal 20 grows in the z direction as a whole as the crystal grows in the a-plane direction. In step-flow growth, information of the a-plane is inherited for crystal growth.

SiC has many polytypes (polymorphs) represented by 3C-SiC, 4H-SiC, 6H-SiC, 15R-SiC, and the like. These polytypes have no difference between their outermost surface structures when viewed in the c-plane direction (<0001> direction), but the structures differ when viewed in the a-plane direction (<11-20> direction). In step-flow growth, since a crystal grows in the a-plane direction, polytypes are less likely to be generated.

In contrast, as shown in FIG. 2B, the c-plane is exposed on the c-plane facet F. On the c-plane facet F, a crystal grows in an island shape in the c-plane direction. As described above, SiC polytypes cannot be distinguished in the c-plane direction, and it is not determined which crystal structure will be formed when a crystal grows in the c-plane direction. For this reason, polytypes are likely to be generated on the c-plane facet F.

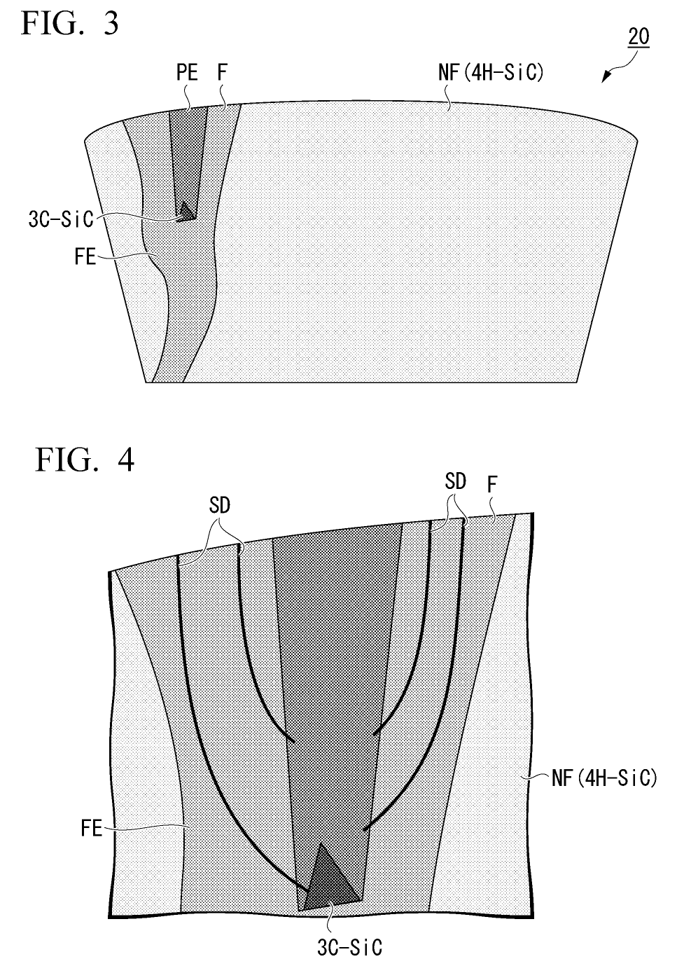

FIG. 3 is a schematic cross-sectional view including the facet region of the SiC single crystal of the present embodiment. In the SiC single crystal of the present embodiment, cubic 3C-SiC is intentionally generated in the facet region FE, which is a region including the c-plane facet F. Originating from this 3C-SiC, a polycrystal region PE is formed in the facet region FE. If there exist 3C-SiC and a polycrystal originating from it on the c-plane facet F, conversion of 4H-SiC to 6H-SiC in the subsequent crystal growth can be curbed.

Since the thermal expansion coefficient of 3C-SiC is approximately 30% smaller than that of 4H-SiC, in 4H-SiC including mixed 3C-SiC, stress is generated around 3C-SiC during a cooling process after crystal growth. Since SiC undergoes plastic deformation at a temperature of 1,100°C or higher, such stress is relieved by becoming a basal plane dislocation. Further, during the cooling process, since stress relief proceeds excessively compared to a crystal having no 3C-SiC, stress is less likely to remain in a part of 4H-SiC, making it possible to obtain a substrate less prone to cracking and warping in subsequent processing steps.

FIG. 4 is a schematic cross-sectional view showing occurrence of threading screw dislocations in the facet region.

The foregoing conversion to 6H-SiC is curbed because generation of polytypes is curbed due to concurrence of the c-plane facet F and threading screw dislocations (TSD) SD. The threading screw dislocations SD are screw-shaped defects. When going around a screw dislocation once, the lattice plane moves up or down by one lattice plane, as in a spiral staircase. In the vicinity of threading screw dislocations exposed on a crystal surface, steps are observed on the surface. A crystal spirally grows in the vicinity of the threading screw dislocations. In spiral growth, since a crystal grows in the a-plane direction, polytypes are less likely to be generated.

Since a mismatch occurs at the atomic level at a boundary between different kinds of polytypes, the threading screw dislocations SD also occur around the areas where 3C-SiC has been generated. The threading screw dislocations SD exposed on the c-plane facet F become permanent step supply sources, and hills (growth hills) with a screw dislocation at their apexes are formed. Since atomic arrangement of 4H-SiC always exists on this step, crystal growth maintaining the atomic arrangement of 4H-SiC is possible without being converted to 6H-SiC.

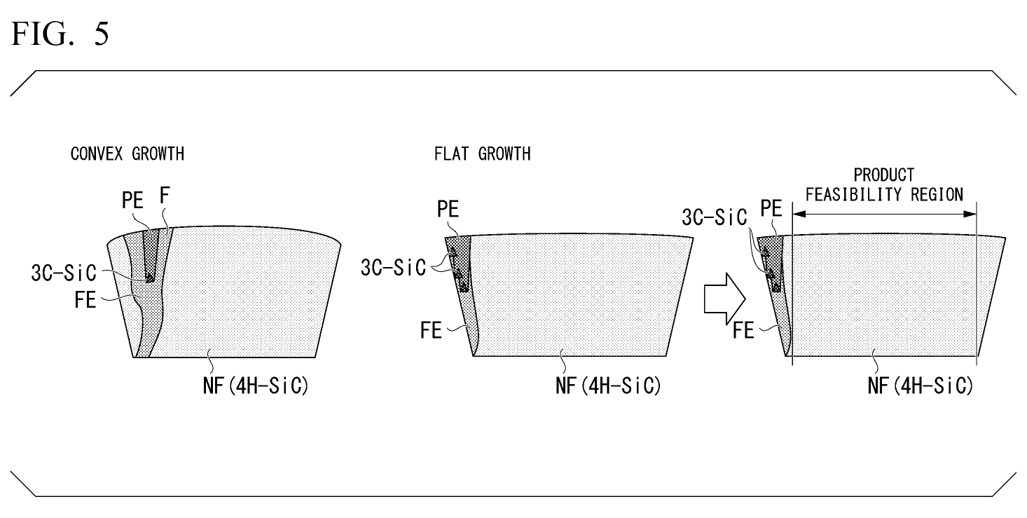

FIG. 5 is a schematic cross-sectional view showing an in-plane position of the facet region in the SiC single crystal.

The facet region FE including 3C-SiC and the threading screw dislocations SD can be at arbitrary positions within a plane of the SiC single crystal. The in-plane position of the facet region FE can be controlled by adjusting known parameters, such as the shape of the crystal growth surface and the offset angle. For example, performing convex growth changes the formation position of the facet region FE toward the center within the plane, and performing flat growth changes it toward the end within the plane. In addition, performing low offset angle growth moves the facet region FE toward the center within the plane, and performing high offset angle growth moves it toward the end within the plane.

Since conversion to 3C-SiC only occurs within the facet region FE including the c-plane facet F, if the in-plane position of the facet region FE is controlled to be near the end, for example, it becomes possible to cut out product SiC wafers from a product-viable region inside of it, which is constituted only of 4H-SiC and does not include 6H-SiC. For this reason, regarding the seed crystal to be used, it is preferable to use a seed crystal which is one size larger than the size of a product wafer.

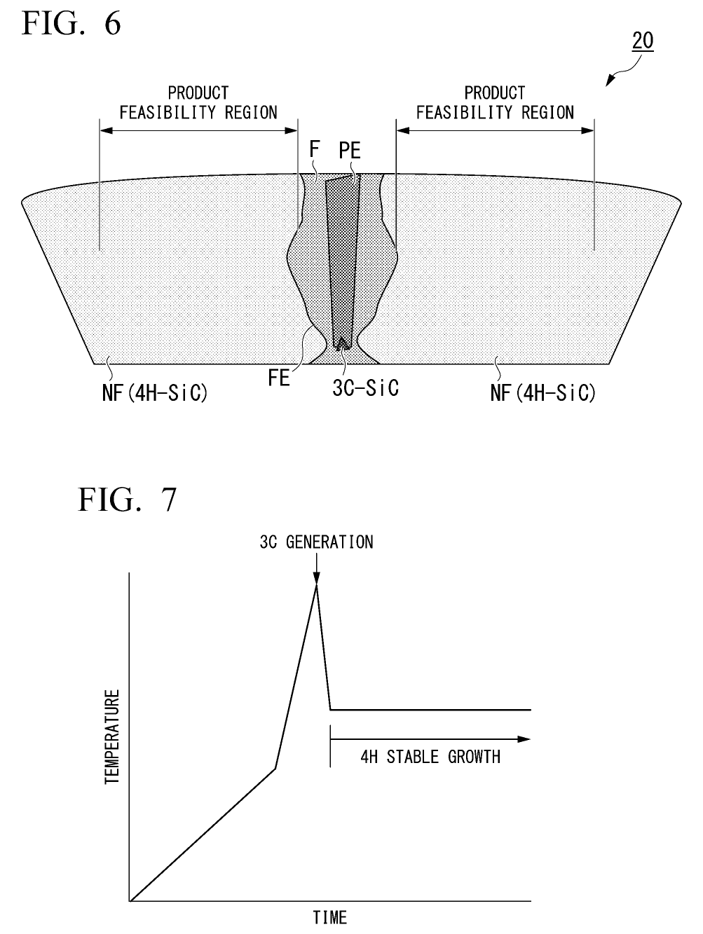

In addition, as shown in FIG. 6, by growing a large-diameter SiC single crystal and setting the in-plane position of the facet region FE near the center, it is also possible to efficiently cut out product SiC wafers while using both its sides as product-viable regions.

Regarding a method for forming 3C-SiC within such a facet region FE, in a sublimation method in which an SiC single crystal is grown by recrystallizing a source gas obtained by sublimating a source SiC on a surface of an SiC seed crystal, as shown in the schematic graph of FIG. 7, it can be realized by temporarily performing high-speed growth exceeding 5 mm/h and performing low-speed growth of 5 mm/h or slower for most of the remaining time.

By rapidly increasing the temperature conditions, 3C-SiC can be generated within the facet region. Thereafter, by lowering the temperature to achieve a stable growth rate, stable growth of 4H-SiC becomes possible in the non-facet region. When growing a long SiC single crystal, since the position of the facet region may change or threading screw dislocations may merge and disappear, it is also preferable to perform such generation of 3C-SiC by rapid temperature increase a plurality of times during the growth of the SiC single crystal.

Regarding such a method for forming 3C-SiC within the facet region FE, methods such as rapidly changing the pressure or incorporating 3C-SiC in the SiC seed crystal in advance are also conceivable.

As above, in the SiC single crystal of the present embodiment, cubic 3C-SiC is included in the facet region which is a region including a c-plane facet, and therefore threading screw dislocations are caused to occur around this 3C-SiC. These threading screw dislocations serve as the step supply sources, thereby always maintaining the atomic arrangement of 4H-SiC and preventing conversion to 6H-SiC. Thus, the non-facet region on the outward side of the facet region can be constituted of 4H-SiC, and a high-quality product SiC wafer constituted only of 4H-SiC and free of 6H-SiC can be obtained by cutting out the product SiC wafer from this non-facet region.

The SiC single crystal of the present embodiment need only be an as-grown SiC single crystal ingot which has not undergone shape processing after crystal growth. In addition, it may also be a cylindrical ingot from which an outer peripheral region of such an as-grown SiC single crystal ingot has been removed by a predetermined width. By processing an SiC single crystal into a cylindrical shape with a substantially constant diameter, for example, the facet region FE in which 3C-SiC and threading screw dislocations exist can be reduced.

In the case of a cylindrical ingot from which an outer peripheral region has been removed by a predetermined width, for example, if growth conditions are controlled to form the facet region FE within a region having a width of 20 mm from an outer peripheral surface toward the center and the outer peripheral region having a width of 20 mm is removed, an SiC single crystal ingot constituted only of 4H-SiC, from which the facet region FE having 3C-SiC and threading screw dislocations existing therein has been removed, can be obtained.

Since conversion from 4H-SiC to 6H-SiC is curbed due to the existence of threading screw dislocations, in an SiC single crystal according to another embodiment of the present invention, the number of threading screw dislocations existing in the facet region and the region on the outward side thereof is larger than the number of threading screw dislocations existing on the center side relative to the facet region.

In this manner, by making the number of threading screw dislocations in the outer peripheral region on the side where the facet region exists larger than that in the region on the center side, the center side of the SiC single crystal can be constituted only of 4H-SiC, resulting in a region having few threading screw dislocations.

In addition, by removing the outer peripheral region of the ingot after crystal growth of the SiC single crystal with a controlled number of threading screw dislocations, a high-quality SiC single crystal ingot composed only of 4H-SiC and having few threading screw dislocations can be made. In addition, by slicing this SiC single crystal ingot, a high-quality SiC substrate can be obtained.

In addition, another SiC substrate according to the present invention is an SiC substrate having 3C-SiC or a polycrystal with a regular orientation in an edge exclusion region on the outer peripheral side and including 4H-SiC on the center side relative to this edge exclusion region.

When performing crystal evaluation of a polished SiC substrate, the region on the outer peripheral portion of the substrate which is excluded from consideration is the edge exclusion region. This outer peripheral portion of the substrate is excluded from a crystal evaluation target because the variation in polishing speed during processing becomes large. The width of the edge exclusion region is usually approximately 2 mm to 3 mm from the peripheral edge.

If the existence of 3C-SiC or a polycrystal with a regular orientation is excluded up to the edge exclusion region, the removal width of the outer peripheral region of the substrate becomes large, making it difficult to obtain a large-diameter SiC substrate. However, as in the present embodiment, by allowing the existence of 3C-SiC or a polycrystal with a regular orientation in the edge exclusion region, it is easy to obtain 4H-SiC in a device formation region on the inward side relative to the edge exclusion region, and it is easy to obtain a large-diameter SiC substrate.

In addition, a constitution in which an epitaxial layer is formed on one main surface of an SiC substrate having the crystal structure of the SiC single crystal described above may be adopted. An epitaxial wafer of the present embodiment can be obtained by forming an epitaxial layer by epitaxial growth on an SiC substrate having the crystal structure of the SiC single crystal described above.

Hereinabove, embodiments of the present invention have been described. However, the embodiments are presented as examples and are not intended to limit the scope of the invention. The embodiments can be performed in various other forms, and various omissions, substitutions, and changes can be made within a range not departing from the gist of the invention. These embodiments and modifications thereof are included in the scope and the gist of the invention, as well as in the scope of the invention described in the claims and their equivalents.

What is claimed is:

1. An SiC single crystal comprising a facet region and a non-facet region,
wherein the facet region included cubic 3C-SiC and the non-facet region is hexagonal 4H-SiC.

2. The SiC single crystal according to claim 1,
wherein the SiC single crystal is an ingot after crystal growth.

3. The SiC single crystal according to claim 1,
wherein the SiC single crystal is an ingot processed into a cylindrical shape.

4. The SiC single crystal according to claim 2,
wherein the facet region exists within a region having a width of 20 mm from an outer peripheral surface toward a center.

5. The SiC single crystal according to claim 1,
wherein the facet region has a threading screw dislocation.

6. A method for manufacturing an SiC substrate using the SiC single crystal according to claim 1, the method comprising:
forming an SiC substrate having an arbitrary diameter by removing an outer peripheral region with an arbitrary width from an outer peripheral surface toward a center.

7. An SiC single crystal comprising a facet region and a non-facet region,
wherein the number of threading screw dislocations existing in the facet region and a region on an outward side thereof is larger than the number of threading screw dislocations existing on a center side relative to the facet region.

8. An SiC epitaxial wafer comprising a SiC substrate which having a facet region and a non-facet region,
wherein an epitaxial layer is formed on one main surface of the SiC substrate where the number of threading screw dislocations existing in the facet region and a region on an outward side thereof is larger than the number of threading screw dislocations existing on a center side relative to the facet region.

9. An SiC single crystal comprising a facet region and a non-facet region,
wherein the number of threading screw dislocations existing in the facet region is larger than the number of threading screw dislocations existing on an outward side relative to the facet region.

10. An SiC epitaxial wafer comprising a SiC substrate which having a facet region and a non-facet region,
wherein an epitaxial layer is formed on one main surface of the SiC substrate where the number of threading screw dislocations existing in the facet region is larger than the number of threading screw dislocations existing on an outward side relative to the facet region.

11. The SiC single crystal according to claim 7,
wherein the SiC single crystal is an ingot processed into a cylindrical shape.

12. The SiC single crystal according to claim 7,
wherein the SiC single crystal is a substrate.

13. An SiC substrate comprising an edge exclusion region,
wherein cubic 3C-SiC or a polycrystal with a regular orientation is provided in the edge exclusion region on an outer peripheral side, and hexagonal 4H-SiC is included on a center side relative to the edge exclusion region.

14. An SiC epitaxial wafer comprising a SiC substrate which having an edge exclusion region,
wherein an epitaxial layer is formed on one main surface of an SiC substrate where 3C or a polycrystal with a regular orientation is provided in an edge exclusion region on an outer peripheral side, and 4H is included on a center side relative to the edge exclusion region.
